(19) United States
(12) Patent Application Publication
(10) Pub. No.: US 2021/0379958 A1
(43) Pub. Date: Dec. 9, 2021

(54) IN-VEHICLE COMPUTER, HEAT DISSIPATING SYSTEM THEREOF, AND VEHICLE WITH THE IN-VEHICLE COMPUTER

(71) Applicants: Inventec (Pudong) Technology Corp., Shanghai (CN); Inventec Corporation, Taipei (TW)

(72) Inventor: Chi-Cheng Hsiao, Taipei (TW)

(21) Appl. No.: 16/903,328

(22) Filed: Jun. 16, 2020

(30) Foreign Application Priority Data
Jun. 9, 2020 (CN) 202010520016.0

(51) Int. Cl. B60H 1/00; G06F 1/20

(52) U.S. Cl. CPC B60H 1/00028; B60H 2001/00185; B60H 2001/00114; G06F 1/206

(57) ABSTRACT

An in-vehicle computer includes a computer casing, an electronic component, a fan, and an air duct. The electronic component and the fan are disposed inside the computer casing. An air inlet of the air duct is located outside the computer casing, and an air outlet thereof is toward or connected to the fan. The fan can generate an airflow for dissipating heat from the electronic component. Therein, the computer casing, the fan, and the air duct therefore form a heat dissipating system. A vehicle includes a vehicle cage and the in-vehicle computer. The in-vehicle computer is disposed inside the vehicle cage. The air inlet of the air duct communicates with the interior space of the vehicle cage, so that when the air conditioner of the vehicle is turned on, the fan can draw the cold air from the cockpit space for enhancing the heat dissipation efficiency.

### BACKGROUND OF THE INVENTION

### 1. Field of the Invention

The present invention relates to an in-vehicle computer, and more particularly to an in-vehicle computer having a heat dissipating system and a vehicle having the in-vehicle computer.

### 2. Description of the Prior Art

As the breadth and depth of vehicle electronic control systems increase in vehicle control, the system complexity and device volume of the vehicle electronic control systems also increase, and the demand for operational stability of vehicle electronic control systems also increases. The demand for the operation stability of the vehicle electronic control systems is also increased. At present, in-vehicle computers are usually simply fixed on the vehicle cage, such as in the rear trunk or other compartments thereof. However, the space of the rear trunk is relatively closed and poorly ventilated, which is not conducive to heat dissipation of the in-vehicle computer. When the vehicle is parked outdoors and exposed to the sun, the temperature inside the vehicle rises rapidly. After the vehicle is started, even if the air condition is turned on, the temperature in the rear trunk still cannot be reduced, which is not conducive to heat dissipation of the in-vehicle computer. Furthermore, at this time, the temperature may seriously affect the operation of the in-vehicle computer, and even affect the driving safety. Therefore, for increasingly complex in-vehicle computers, there is a need to provide an effective heat dissipation mechanism.

### SUMMARY OF THE INVENTION

An objective of the invention is to provide an in-vehicle computer, which has a heat dissipating system capable of drawing air from a cockpit space for enhancing the heat dissipation efficiency.

An in-vehicle computer according to the invention includes a computer casing, an electronic component, a fan, and an air duct. The computer casing has an accommodating space and an opening communicating with the accommodating space. The electronic component is disposed in the computer casing. The fan is disposed in the accommodating space and has a suction port and an exhaust port. The fan generates an airflow for dissipating heat from the electronic component. The air duct is exposed out the computer casing and passes through or is connected to the opening. The air duct has an air inlet and an air outlet. The air inlet is located outside the computer casing. The air outlet is toward or connected to the suction port. Thereby, through the air duct extending outward, the in-vehicle computer can draw air from other places (e.g. cool air from the cockpit space) without the limitation of the location of the in-vehicle computer, so as to enhance the heat dissipation efficiency.

Another objective of the invention is to provide a vehicle, which includes an in-vehicle computer like the above. The heat dissipating system of the in-vehicle computer can draw air from a cockpit space for enhancing the heat dissipation efficiency.

A vehicle computer according to the invention includes a vehicle cage and an in-vehicle computer. The vehicle cage has a cockpit space. The in-vehicle computer is disposed in the vehicle cage and includes a computer casing, an electronic component, a fan and an air duct. The computer casing has an accommodating space and an opening communicating with the accommodating space. The electronic component is disposed in the computer casing. The fan is disposed in the accommodating space and has a suction port and an exhaust port. The fan generates an airflow for dissipating heat from the electronic component. The air duct is exposed out the computer casing and passes through or connected to the opening. The air duct has an air inlet and an air outlet. The air inlet is located outside the computer casing. The air outlet is toward or connected to the suction port. The air duct communicates with the cockpit space through the air inlet. Thereby, through the air duct extending outward, the in-vehicle computer can draw cool air from the cockpit space (e.g. when an air condition of the vehicle is turned on) without the limitation of the location of the in-vehicle computer in the vehicle cage, so as to enhance the heat dissipation efficiency.

Another objective of the invention is to provide a heat dissipating system, which is used for an in-vehicle computer and can draw air from a cockpit space for enhancing the heat dissipation efficiency of the in-vehicle computer.

A heat dissipating system according to the invention is used for an in-vehicle computer and includes a computer casing, a fan, and an air duct. The computer casing has an accommodating space and an opening communicating with the accommodating space. The fan is disposed in the accommodating space and has a suction port and an exhaust port. The air duct is exposed out the computer casing and passes through or connected to the opening. The air duct has an air inlet and an air outlet. The air inlet is located outside the computer casing. The air outlet is toward or connected to the suction port. Thereby, through the air duct extending outward, the in-vehicle computer can draw air from other places (e.g. cool air from the cockpit space) without the limitation of the location of the in-vehicle computer, so as to enhance the heat dissipation efficiency.

Compared with the prior art, the in-vehicle computer, the heat dissipating system thereof, and the vehicle with the in-vehicle computer according to the invention can draw cool air from the cockpit space through the air duct extending outward without the limitation of the location of the in-vehicle computer in the vehicle cage, so that the in-vehicle computer can effectively dissipate heat and operate stably, which solves the problem in the prior art that the in-vehicle computer is limited by its location and is not easy to dissipate heat.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a vehicle with an in-vehicle computer according to an embodiment.

FIG. 2 is a schematic diagram illustrating the in-vehicle computer in FIG. 1.

FIG. 3 is a partially exploded view of the in-vehicle computer in FIG. 2.

FIG. 4 is a schematic diagram illustrating a cross section of the in-vehicle computer along the line X-X in FIG. 2.

FIG. 5 is a schematic diagram illustrating a cross section of a structural configuration of a fan and an air duct in FIG. 4 according to an embodiment.

FIG. 6 is a schematic diagram illustrating the interior of the vehicle at a back seat in FIG. 1.

### DETAILED DESCRIPTION

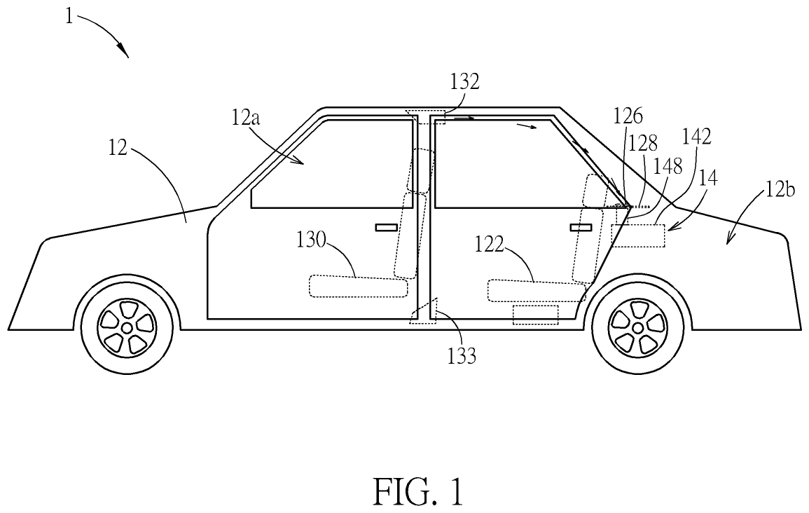

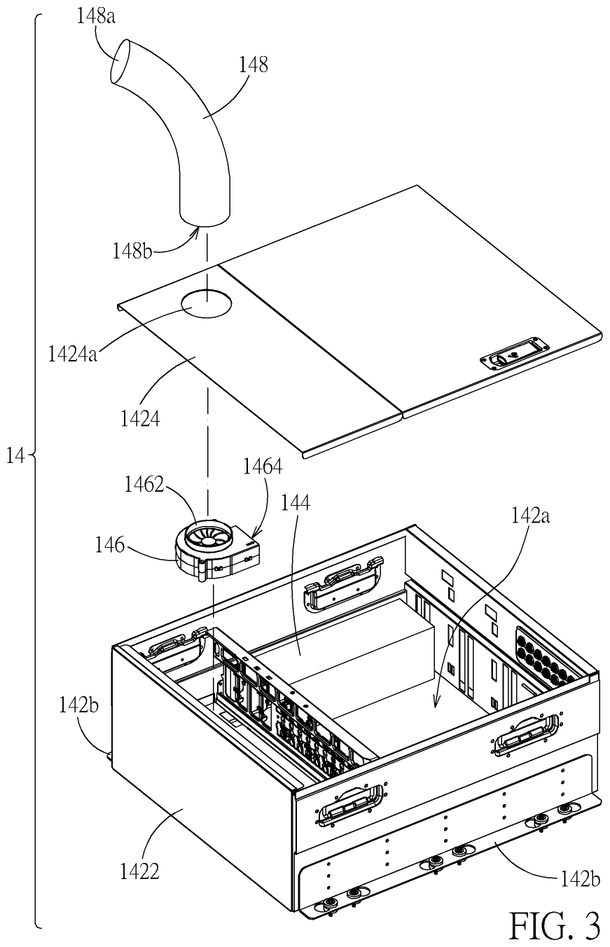

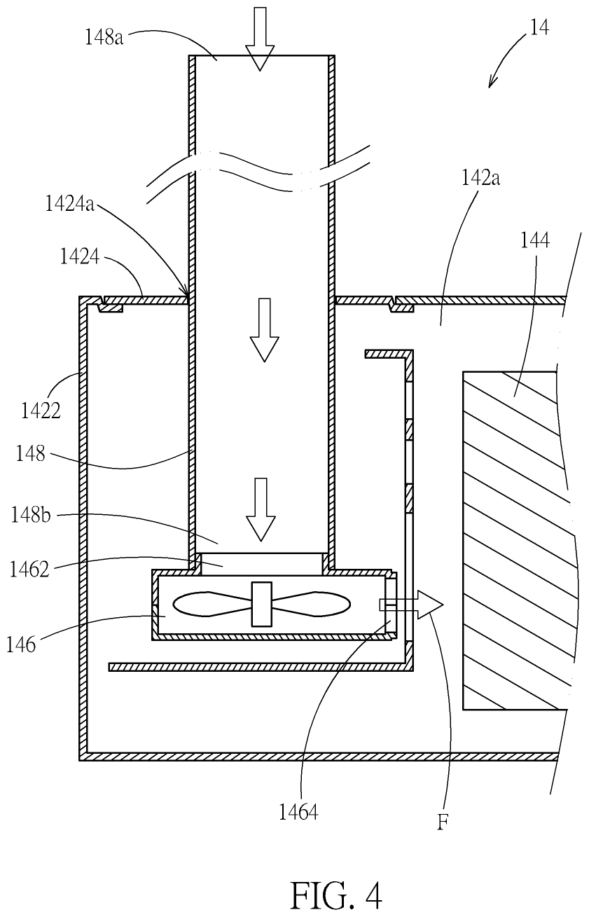

Please refer to FIG. 1 to FIG. 4. A vehicle 1 according to an embodiment includes a vehicle cage 12 and an in-vehicle computer 14 (of which the profile in FIG. 1 is shown in dashed lines) disposed in the vehicle cage 12. The in-vehicle computer 14 includes a computer casing 142, an electronic component 144, a fan 146, and an air duct 148. The computer casing 142 includes a base 1422 and a top cover 1424. The base 1422 and the top cover 1424 are engaged to form an accommodating space 142a. The electronic component 144 (shown by a solid block for drawing simplification; in practice, the electronic component 144 can be but not limited to a system mainboard, a memory module, a hard drive disk, a power supply module, an expansion card, or other components that will produce heat during operation) is disposed in the accommodating space 142a of the computer casing 142. The fan 146 (e.g. but not limited to an axial fan, a centrifugal fan, or a blower) has a suction port 1462 and an exhaust port 1464. The fan 146 can generate an airflow F (indicated by hollow arrows in FIG. 4) for dissipating heat from the electronic component 144. The air duct 148 is exposed out the computer casing 142 and has an air inlet 148a and an air outlet 148b. The air inlet 148a is located outside the computer casing 142. The air outlet 148b is toward or connected to the suction port 1462. Thereby, the fan 146 can draw air away from the computer casing 142 through the air duct 148, so as to improve the temperature of the intake air for enhancing the heat dissipation effect of the electronic component 144.

In the embodiment, the fan 146 is disposed in the accommodating space 142a of the computer casing 142. The top cover 1424 has an opening 1424a communicating with the accommodating space 142a. The air duct 148 passes through the opening 1424a and is connected to the suction port 1462 of the fan 146 through the air outlet 148b. Therein, it is practicable to also fix the air duct 148 to the opening 1424a (e.g. by means of structure locking or adhesive) and further to seal the gap between the air duct 148 and the opening 1424a for enhancing the dust resistance of the computer casing 142. The exhaust port 1464 of the fan 146 is toward the electronic component 144. Thereby, in principle, the fan 146 only sucks in the air introduced through the air duct 148 to form an airflow F with lower temperature for directly dissipating heat from the electronic component 144. However, it is not limited thereto in practice. For example, the air duct 148 extends into the accommodating space 142a through the opening 1424a, but not to be directly connected to the suction port 1462 of the fan 146. The air outlet 148b (or the opening thereof) is still toward the suction port 1462 of the fan 146. Such structural configuration still can make the fan 146 effectively suck in the air introduced through the air duct 148.

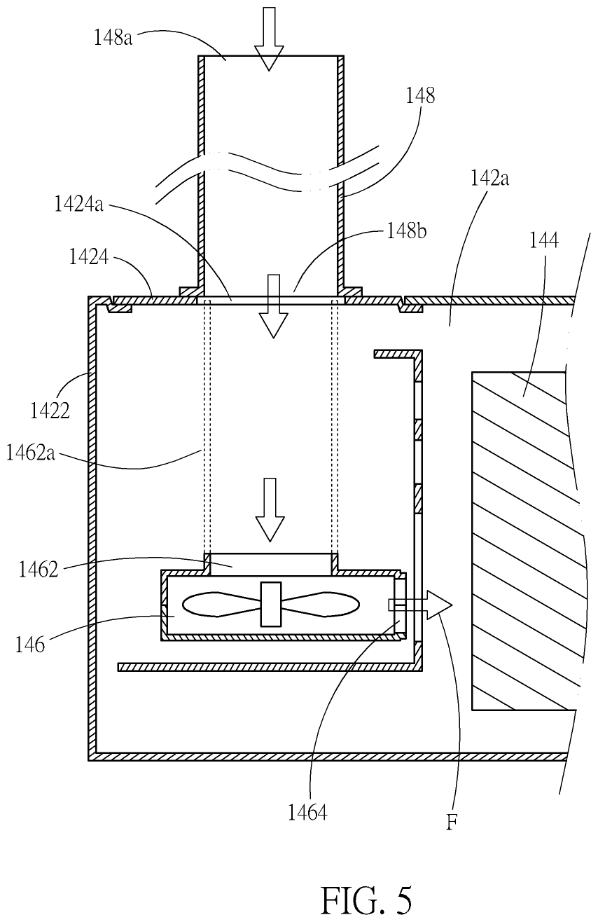

For another example, as shown by FIG. 5, the air outlet 148b of the air duct 148 is connected to the outer side of the opening 1424a (or connected to the inner side of the opening 1424a in practice), so that basically, the air duct 148 is entirely located outside the computer casing 142. The suction port 1462 of the fan 146 is still aligned with the opening 1424a, so the fan 146 still can effectively suck in the air introduced into the computer casing 142 (or the accommodating space 142a thereof) through the air duct 148. In this case, it is practicable to dispose a guiding structure in the accommodating space 142a between the opening 1424a and the suction port 1462 of the fan 146, for enhancing the effect of the fan 146 sucking in the air introduced through the air duct 148. For another example, the suction port 1462 of the fan 146 structurally extends upward to form a guiding structure 148c (e.g. a tubular structure, as shown in dashed lines in FIG. 5) to approach or contact, connect with the opening 1424a, for the fan 146 to effectively suck in the air introduced through the air duct 148. For another example, the guiding structure passes through the opening 1424a to be connected to the air outlet 148b of the air duct 148 (e.g. by sleeving the air outlet 148b on the guiding structure).

In addition, a hard tube or a flexible tube, for example but not limited to a metal or plastic tube, can be used as the air duct 148. The flexibility of the flexible tube can be obtained by its material or structure (e.g. forming creases on the tube body). It is easy to install the air duct 148 due to its flexibility.

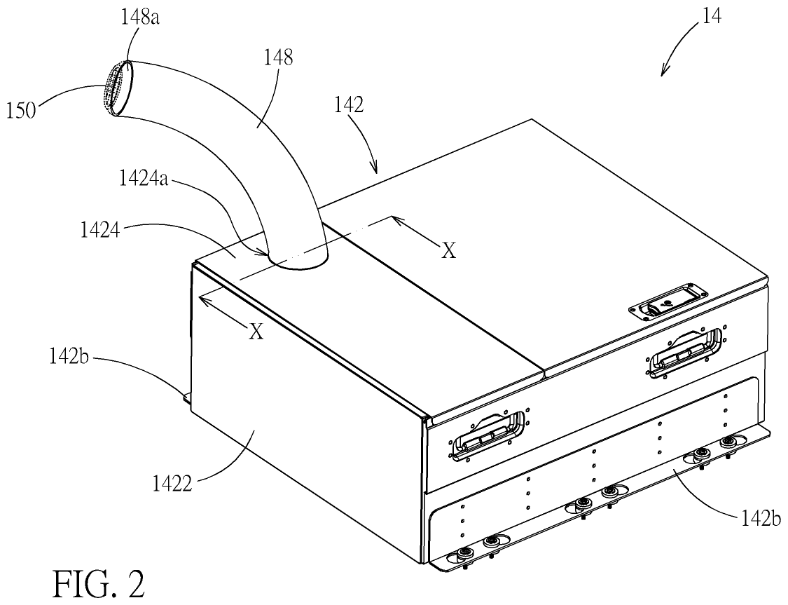

In the embodiment, the in-vehicle computer 1 can further include a filter 150 (shown in dashed lines in FIG. 2), disposed at the air inlet 148a of the air duct 148. The filter 150 can reduce the amount of particles (e.g. dust) contained in the air introduced into the computer casing 142 by the air duct 148. In practice, the filter 150 can be realized by a common filter (e.g. including but not limited to one or more filter screens or cloths made of fibers or porous materials), which will not be described in addition. Furthermore, in the embodiment, the filter 150 is assembled to the air inlet 148a in a separate way. However, in practice, the filter 150 also can be structurally integrated with the air inlet 148a of the air duct 148 (e.g. filling up the air inlet 148a with one or more filter screens or cloths made of fibers or porous materials), which will not be described in addition.

As shown by FIG. 1, in the embodiment, the vehicle cage 12 has a cockpit space 12a (including space for a driver and passengers to ride and move). Aback seat 122 is disposed in the cockpit space 12a. The in-vehicle computer 14 is disposed in the rear trunk 12b close to the back seat 122 (which may be regarded as being disposed between the rear trunk 12b and the back seat 122), for example fixed to a structural frame of the vehicle cage 12 by two fixing parts 142b at two sides of the computer casing 142. By properly disposing the air duct 148 so as to make the air duct 148 communicate with the cockpit space 12a through the air inlet 148a, the in-vehicle computer 14 can draw (by the fan 146) air with lower temperature (relative to the environment temperature where the computer casing 142 is disposed) in the cockpit space 12a through the air duct 148, so as to obtain better heat dissipation effect.

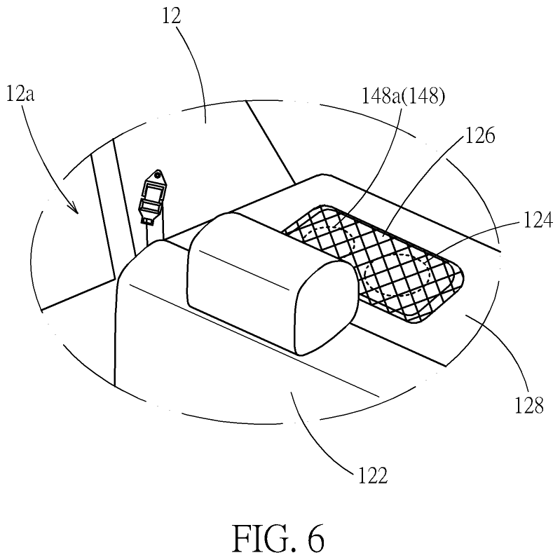

Please also refer to FIG. 1 to FIG. 3, and FIG. 6. The vehicle cage 12 includes a speaker 124 (of which the profile hidden by the speaker mesh cover 126 is shown in dashed lines in FIG. 6) and a speaker mesh cover 126 covering the speaker 124. The speaker 124 is located behind the back seat 122 (or the headrest thereof) and is usually fixed on a structural plate or a decorative plate 128. The speaker mesh cover 126 is exposed from the cockpit space 12a (and also can be fixed on the decorative plate 128) and simultaneously covers the speaker 124 and the air inlet 148a (of the air duct 148) (of which the profile hidden by the speaker mesh cover 126 is shown in dashed lines in FIG. 6), giving consideration to both appearance and beauty. In practice, the air inlet 148a and the filter 150 also can be structurally integrated with the speaker mesh cover 126, for example by disposing fibers or porous materials with filtering function inside the speaker mesh cover 126 and connecting the air inlet 148a with the speaker mesh cover 126 so as to make the fibers or porous materials be located at the air inlet 148a.

Furthermore, in general, the speaker mesh cover 126 is located at a prominent place in the cockpit space 12a (e.g. the place behind the head rest of the back seat 122 in the embodiment). The air circulates. Thereby, when the air condition of the vehicle 1 is turned on, the fan 146 can effectively draw cool air through the air inlet 148a for enhancing the heat dissipation efficiency. Furthermore, in some car models, an air outlet 132 (indicated by a block in dashed lines in FIG. 1) is disposed at the upper middle of the cockpit space 12a (substantially between the front seat 130 and the back seat 122). The cool air from the air outlet 132 can effectively blows toward the speaker mesh cover 126 (of which the flowing path is indicated by arrows in FIG. 1), which helps the fan 146 to effectively draw the cool air through the air inlet 148a.

In addition, in the embodiment, although the in-vehicle computer 14 is not directly disposed in the cockpit space 12a, the in-vehicle computer 14 still can draw the cool air from the cockpit space 12a through the air duct 148. In practice, the in-vehicle computer 14 also can be disposed in the cockpit space 12a, but the location of the in-vehicle computer 14 may be poorly ventilated (e.g. under the seat which is indicated by a block in dashed lines under the back seat 122 in FIG. 1). The fan 146 still can draw cool air in the cockpit space 12a smoothly by properly arranging the air duct 148. For example, in some car models, an air outlet 133 is disposed on the bottom plate in the cockpit space 12a. Then, the air inlet 148a of the air duct 148 can be disposed to be toward or close to the air outlet 133, so that the fan 146 can draw the cool air. Furthermore, in actual use, if the weather is hot outside the vehicle 1, even when the air condition of the vehicle 1 is not turned on, the air temperature in the cockpit space 12a is still lower than other place inside the vehicle cage 12 in principle (e.g. the rear trunk 12b), so that the fan 146 still can draw the air with relatively low temperature through the air duct 148 so as to form an airflow with relatively low temperature.

As described above, the computer casing 142, the fan 146, and the air duct 148 of the in-vehicle computer 14 installed in the vehicle 1 form a heat dissipating system that draws the air with lower temperature through the air duct 148 to form an airflow with lower temperature for providing better heat dissipation effect to the electronic component 144.

In an embodiment according to the invention, the technology of the present invention can be applied to in-vehicle devices, such as self-driving cars, electric cars, semi-autonomous cars, and so on.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An in-vehicle computer, comprising:
a computer casing, having an accommodating space and an opening communicating with the accommodating space;
an electronic component, disposed in the computer casing;
a fan, disposed in the accommodating space and having a suction port and an exhaust port, the fan generating an airflow for dissipating heat from the electronic component; and
an air duct, exposed out the computer casing and passing through or connected to the opening, the air duct having an air inlet and an air outlet, the air inlet being located outside the computer casing, the air outlet being toward or connected to the suction port.

2. The in-vehicle computer according to claim 1, further comprising a filter, disposed at the air inlet.

3. The in-vehicle computer according to claim 1, wherein the fan is an axial fan, a centrifugal fan, or a blower, and the exhaust port is toward the electronic component.

4. An vehicle, comprising:
a vehicle cage, having a cockpit space; and
an in-vehicle computer, disposed in the vehicle cage, the in-vehicle computer comprising:
a computer casing, having an accommodating space and an opening communicating with the accommodating space;
an electronic component, disposed in the computer casing;
a fan, disposed in the accommodating space and having a suction port and an exhaust port, the fan generating an airflow for dissipating heat from the electronic component; and
an air duct, exposed out the computer casing and passing through or connected to the opening, the air duct having an air inlet and an air outlet, the air inlet being located outside the computer casing, the air outlet being toward Or connected to the suction port, the air duct communicating with the cockpit space through the air inlet.

5. The vehicle according to claim 4, wherein the in-vehicle computer further comprises a filter, disposed at the air inlet.

6. The vehicle according to claim 4, wherein the fan is an axial fan, a centrifugal fan, or a blower, and the exhaust port is toward the electronic component.

7. The vehicle according to claim 4, wherein the vehicle cage comprises a speaker mesh cover, disposed behind a back seat in the vehicle cage and exposed from the cockpit space, and the speaker mesh cover covers the air inlet.

8. A heat dissipating system, used for an in-vehicle computer, the heat dissipating system comprising:
a computer casing, having an accommodating space and an opening communicating with the accommodating space;
a fan, disposed in the accommodating space and having a suction port and an exhaust port; and
an air duct, exposed out the computer casing and passing through or connected to the opening, the air duct having an air inlet and an air outlet, the air inlet being located outside the computer casing, the air outlet being toward or connected to the suction port.

9. The heat dissipating system according to claim 8, further comprising a filter, disposed at the air inlet.

10. The heat dissipating system according to claim 8, wherein the fan is an axial fan, a centrifugal fan, or a blower.
